(19) United States
(12) Patent Application Publication
(10) Pub. No.: US 2009/0159891 A1
(43) Pub. Date: Jun. 25, 2009

(54) MODIFYING A SURFACE IN A PRINTED TRANSISTOR PROCESS

(75) Inventors: Jurgen H. Daniel, San Francisco, CA (US); Michael L. Chabinyc, San Francisco, CA (US); Ana C. Arias, San Carlos, CA (US)

Correspondence Address: MARGER JOHNSON & MCCOLLOM/PARC, 210 MORRISON STREET, SUITE 400, PORTLAND, OR, 97204, US

(73) Assignee: PALO ALTO RESEARCH CENTER INCORPORATED, Palo Alto, CA (US)

(21) Appl. No.: 11/962,532

(22) Filed: Dec. 21, 2007

(51) Int. Cl. H01L 21/336; H01L 29/786

(52) U.S. Cl. 257/66; 438/158; 257/E21.411; 257/E29.273

(57) ABSTRACT

A method of forming an electronic device includes depositing a dielectric, forming a first functional material layer having a first surface energy, depositing at least one first at least semiconductive feature of the device, forming a second functional material layer to provide a surface having a second surface energy, and depositing at least one second at least semiconductive feature of the device to connect to the first at least semiconductive feature of the device. A method of forming an electronic device includes depositing a first, dielectric material, depositing a second material, depositing at least one first at least semiconductive feature of the device on the second material, altering the second material to form a altered second material, and depositing at least one at least semiconductive feature from solution to connect the first semiconductive feature of the device. An electronic device has a substrate, a dielectric layer, a first functional layer having a first surface energy, at least one first at least semiconductive feature on the first functional layer, a second functional layer in a region between adjacent to the first at least semiconductive features, and at least one second at least semiconductive feature on the second functional layer.

### BACKGROUND

Printed electronics may allow printing of electronic circuits in a faster and more cost-effective method than the typical photolithography-based processes which employ vacuum deposition methods.

In one example, a printing process can form a bottom gate thin film transistor (TFT) by printing the source and drain onto the gate dielectric. However, many gate dielectric materials are too hydrophobic to allow printing, such as jet-printing, of materials. They essentially repel the liquid used in the printing process, such as nanoparticles of silver in solution. The printing process generally requires a liquid for forming the lines.

The hydrophobic nature of the dielectric material causes problems in the printing process. Some dielectrics will allow printing of liquids, and in one example, a silicon dioxide coating received the printing liquid to form electrodes and then the surface was made hydrophobic using a thin layer of polysilsesquioxane or a fluorocarbon. This approach causes contact resistance because the layer also covers the printed electrode material. On the other hand, silane coatings can form very thin layers causing low contact resistance but on many polymer dielectrics they are not very efficient because of the lack of silanol or hydroxyl groups.

Another factor to take into account in the formation of TFTs is that higher mobility in the TFT allows for better performance of the transistor. Higher mobility is often observed if the organic semiconductor is deposited onto a hydrophobic gate-dielectric.

Other approaches require very fine control of the surface treatments. If the surface becomes too hydrophobic, it can lead to de-wetting or formation of bulges in the printed lines. If the surface becomes too hydrophilic, it can lead to excessive spreading.

### BRIEF DESCRIPTION OF THE DRAWINGS

FIG. 1 shows a graph of times of ozone treatments versus water contact angle.

FIGS. 2-8 show various stages of an embodiment of a process of forming a bottom-gate bottom-contact printed thin-film-transistor.

FIGS. 9-13 show various stages of an embodiment of forming a bottom-gate top-contact printed thin-film transistor.

FIGS. 14-20 show various stages of an alternative embodiment of a process of forming a bottom-gate bottom-contact printed thin-film-transistor.

### DETAILED DESCRIPTION OF THE EMBODIMENTS

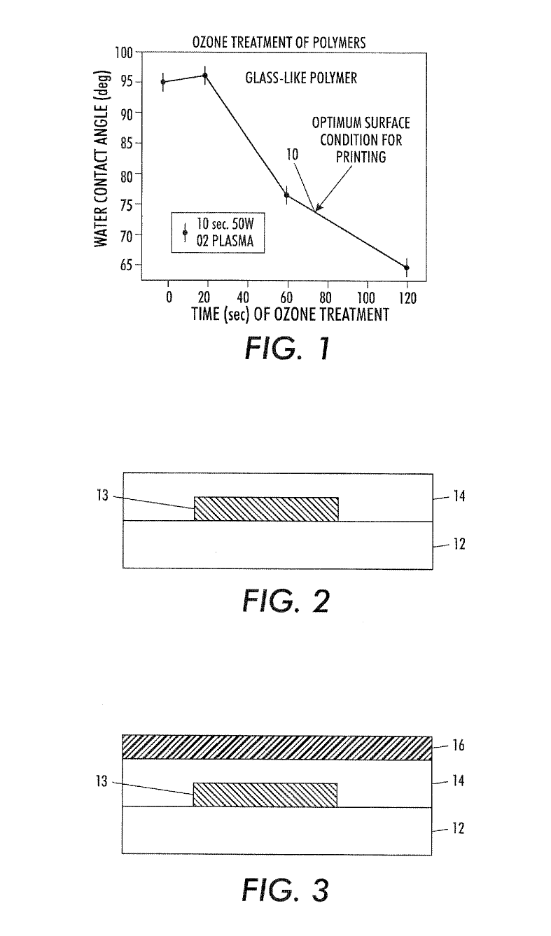

FIG. 1 shows that the surface energy, which affects the water contact angle, of a glass-like hydrophobic polymer can be lowered by exposing it to ozone or a plasma, such oxygen or carbon dioxide plasma. By choosing the appropriate amount of time during which the polymer is exposed to the plasma, one can find a condition that allows jet-printing of narrow continuous lines with a specific ink. As mentioned above, if the surface remains too hydrophobic it can lead to de-wetting or bulges in the printing lines. If the surface becomes too hydrophilic, it can lead to excessive spreading of the printed ink.

In FIG. 1 lines of silver nanoparticles in solution, such as silver nanoparticles dispersed in a mixture of polyethylene glycol and water, were printed. Such solutions are commercially available from companies such as Cabot, Corp. The point 10 on the graph of FIG. 1 shows a point in time at which a glass-like polymer, such as a polysilsesquioxane, exposed to ozone becomes optimal for jet printing. A glass-like polymer, as that term is used here, is any polymer in which silicon-oxygen (Si—O) bonds are present. Reactive treatment of these materials can cause the formation of silanol (Si—OH) groups. Examples include silicones, with one oxygen per silicon molecule, or polysilsesquioxanes, with 1.5 oxygens per silicon or silica nanoparticle composites. Other polymers may also receive these treatments and become useful for jet printing. For example, a polymer may contain alumina, zirconia, hafnium oxide or barium titanate particles, particularly nanoparticles. The type of treatment depends largely upon the composition of the polymer.

In general, this discussion will focus on polymers that have functionality that can be activated or induced by a reactive treatment such as ozone or O₂ plasma. A silicone polymer is such an example. Other materials may also be treated by an oxygen plasma or ozone, such as inorganic materials, including silicon dioxide, silicon nitride, aluminum oxide or zirconium oxide. Here, the treatment also makes the surface more reactive and it cleans off surface contamination. Apart form oxygen plasmas or ozone, other methods may be used to activate the surface of a material, including carbon dioxide plasma, argon or nitrogen plasma or others.

An issue may arise in controlling this treatment for large areas because precise control of the plasma or of the ozone concentration is required. However, it is possible to treat the polymer by a plasma or ozone until the surface becomes extremely hydrophilic which means that many silanol or hydroxyl groups are exposed. A silane or other surface modifier is then attached to the surface, such as by liquid or vapor deposition. Rather dense silanization is possible on glass-like polymers due to the presence of silanol groups on the surface.

In one embodiment, a methylated polysilsesquioxane is treated with an oxygen plasma and then the surface is functionalized with a long-chain alkylsilane (octadecyltrichlorosilane:OTS). Many silanes are known and the functionality determines the surface energy. For example, the hydrophobicity increases in the following list of silanes: tetraethoxysilane, methyltrimethoxysilane, propyltrimethoxysilane, isobutyltrimethoxysilane, phenyltrimethoxysilane, n-octyltriethoxysilane. A silane coating can be chosen according to the requirements for the surface tension of the ink to be printed. It should be noted that instead of silanes, also silazanes such as hexamethyldisilazane (HMDS) can be used to functionalize the surface.

A surface becomes functionalized when a molecule layer with functional groups such as amine, ammonium, ester, epoxy, etc., is attached to the surface via physisorption or chemisorption. In the case of silanes, the silane molecules possess a chloro- or alkoxysilane anchor group that attaches to the substrate and a functional head group such as —NH₂, —CH₃, etc. In between, there may be a flexible alkyl spacer ((CH₂)ₙ) that separates the two groups. The functionality of the layer determines surface properties such as friction, adhesion, chemical resistance, wettability or surface charging, etc.

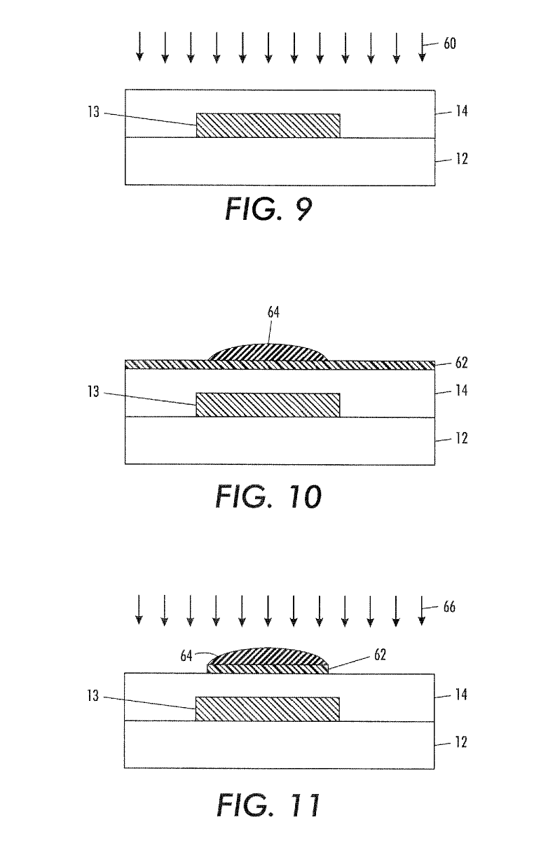

FIGS. 2-8 show an embodiment of a process for forming an electronic device using a printing method such as jet-printing. In the embodiments of FIGS. 2-8, the electronic device formed consists of a bottom-gate, bottom-contact thin film transistor using a material deposited on top of the gate dielectric for functionalization. FIGS. 9-13 show an embodiment of a process for forming a top-contact thin film transistor using the gate dielectric material for functionalization. In a bottom-contact thin-film transistor, the source and drain contacts are placed underneath the semiconductor, in a top-contact device, the source and drain contacts are on top of the semiconductor. FIGS. 14-20 show an embodiment of a process for forming a bottom-contact thin film transistor using a material on top of the gate dielectric for functionalization, wherein the functionalization process is an alternative process from that shown in FIGS. 2-8.

In FIG. 2, a first material 14, generally an insulator, such as a polymer or an oxide or a nitride, is deposited on a substrate 12 that has formed upon it a gate electrode of a transistor or other contact 13. The electrode 13 may be deposited by a printing method, but it may be also deposited by more conventional methods such as metal evaporation through a shadow mask or it may be defined by vacuum deposition of a conductor and patterning using photolithography or laser-patterning. An example of a solution deposited electrode material is the conductive polythiophene polymer PEDOT:PSS or silver deposited from a solution of silver nanoparticles. An example of a vacuum deposited electrode material is a layer of chromium or a dual layer of chromium and gold.

Layer 14 may be deposited from a solution by a printing method, by spin-casting, doctor-blading, curtain-coating, spray coating or other known solution coating methods. Materials such as polyvinylphenol (PVP), SU-8 epoxy polymer manufactured by Microchem Corp., spin-on-glass or polyimide are examples of insulators deposited from solution. Layer 14 may be also deposited by a physical or chemical vapor deposition method (PVD or CVD) such as thermal evaporation or plasma deposition, but also by atomic layer deposition (ALD). The material may be an oxide such as silicon dioxide or aluminum oxide, a nitride such as silicon nitride or a polymer such as parylene, for example.

In FIG. 3, a functionalizable material 16, such as a glass-like polymer, is deposited on the material 14. This layer 16 is required if the underlying layer 14 is not functionalizable or poorly functionalizable. However, if the layer 14 consists already of a functionalizable material, such as an oxide, for example, then this second layer 16 does not have to be additionally deposited and layer 16 in FIG. 3 is regarded as a part of layer 14.

A functionalizable material has the properties that its surface can be modified by attaching molecules, such as self assembled monolayers (SAMs). In order to be functionalizable, the material has to possess an abundant amount of reactive groups to which the molecules can attach and form a strong bond. In most cases this bond would be a covalent bond, but weaker bonding mechanisms such as hydrogen-bridge bonds or van-der-Waals bonding forces may also play a role. The material 16 may be also deposited from a solution by jet-printing, spin-casting, spray coating, dip-coating, doctor blading, etc. However, it may also be deposited by a physical or chemical vapor deposition method.

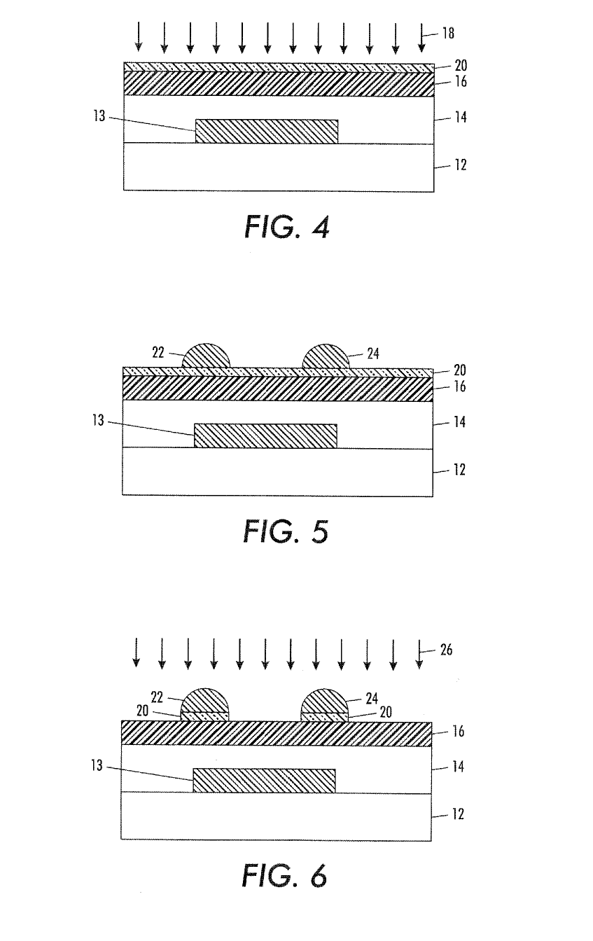

FIG. 4 shows that the material 16 is treated with a plasma such as an oxygen plasma or ozone 18 in order to render the surface more reactive. This process may be optional, but often results in better attachment of the subsequent layer. A surface functionalization is then performed by exposing the surface to reactive molecules 20, also here referred to as ‘surface modifier’. Examples of such reactive molecules or surface modifiers are silane compounds or silazanes. They may be applied by exposing the surface to a solution of the molecules in a solvent or by exposing the surface to a vapor of molecules.

The molecular layer, either a monolayer or multilayer, 20 provides a surface with a first surface energy. In the example of a silane surface modification, the surface energy is determined by the polymer group on the silane. For example, octadecyltrichlorosilane (OTS) or a fluoro-silane results in hydrophobic surfaces while epoxy silanes such as 3-glicidoxy-propyl-trimethoxy silane or amino silanes such as amino-trimethoxy silane result in hydrophilic surfaces. A range of functional silanes exists such as the ones from Gelest, Inc.

In FIG. 5, the source 22 and drain 24 of a transistor structure are deposited on the functional coating 20. The lines or features are deposited by a printing method such as jet-printing. If the surface tension and viscosity of the ink and the surface energy of the layer 20 are in the correct range, then narrow, continuous lines can be printed. Here, the source and drain features may be consist of printed nano silver or organic conductor such as PEDOT:PSS or polyaniline. Apart form the source and drain features, other structures may be printed on this layer 20 as well. In the case of a display backplane, the data bus lines and the pixel pads would be printed on layer 20. For ideal printing conditions, the ink and the layer 20 have to be carefully chosen.

A plasma/ozone treatment or photodecomposition 26 then removes the functional coating 20 in FIG. 6, again exposing the reactive surface groups of layer 16. However, portions of the coating 20 remain under the source 22 and drain 24.

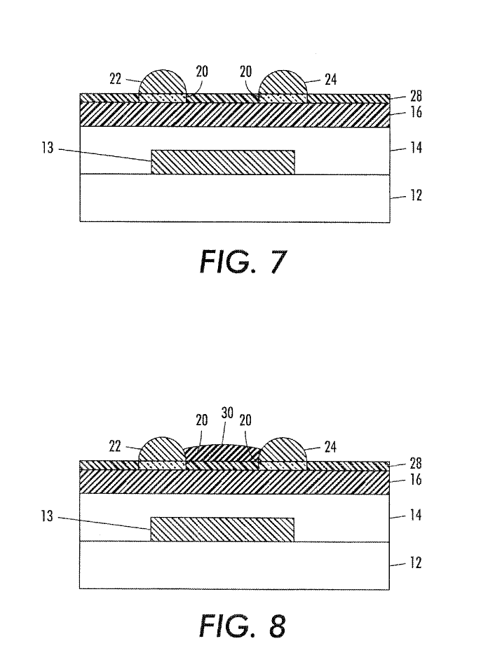

In FIG. 7, a new, second functional coating 28 is deposited on the now-exposed functionalizable material layer 16. Again, portions of the first coating 20 remain under the source and drain. The second coating 28 provides a surface having a second surface energy. The second coating may be also a silane coating. For the second coating a hydrophobic or low-surface energy property is often desirable. This can be achieved with OTS or hexamethyldisilazane (HMDS), for example. Some of this material may deposit also on the contacts 22 and 24 and help to reduce contact resistance between the contacts and the later deposited semiconductor. Such reduced contact resistance has been observed for example in the case of certain silanes as the surface coating. Alternatively, the material deposited on the contacts may be selectively removed by a cleaning step.

In FIG. 8, a semiconductor 30 is deposited on the hydrophobic surface. The semiconductor may be deposited from a solution with a method such as inkjet-printing. The semiconductor may be an organic semiconductor such as a semiconducting polymer, or an oligomer or a precursor for a small-molecule organic semiconductor. Examples are polythiophenes such as P3HT, PQT-12, PBTTT, or pentacene precursors such as TIPS pentacene, but also phthalocyanines, tetrabenzoporphyrins and others. The semiconductor may be also an inorganic semiconductor deposited from a dispersion or from a precursor solution. Examples are carbon nanotube semiconductors, nanowire or nanoparticle semiconductors such as silicon or zinc oxide nanowires or particles or silicon precursors.

The process described in FIGS. 2-8 shows the fabrication of a bottom-gate, bottom-contact transistor. In a bottom-contact transistor, the semiconductor lies on top of the source-drain contacts. However, in some cases it is advantageous to deposit the semiconductor first and then deposit the source and drain contacts. This usually leads to a lower contact resistance. This will be discussed with regard to FIGS. 9-13. As mentioned earlier, the hydrophobic surface enhances the transistor performance by allowing for higher mobility.

Typically, in the described process the second functional coating would have a lower surface energy than the first functional coating. For example, in order to jet-print silver lines from a water/ethylene glycol-based silver nanoparticle solution, the water contact angle of the first functional coating would be between 50 and 80 deg. This has been achieved for example with a coating of HMDS (hexmethyldisilazane). For depositing an organic semiconductor such as the polythiophene PQT-12 on the second functional layer, a surface with a higher water contact angle is desirable, ideally above 90 deg. This can be achieved for example, with a coating of OTS (octodecyltrichlorosilane).

This process constitutes merely one embodiment of a process for manufacturing a TFT using jet printing. The applications of this process may include other types of devices in which contacts, shown as a transistor source and drain, are connected using jet-printing processes, as shown by the printing of the organic semiconductor in FIG. 8.

The resulting device, shown in FIG. 8, has the substrate 12, a gate electrode having a gate dielectric on it. A coating such as the functionalizable layer 16 resides on the gate dielectric and has a first functional layer 20 residing upon it. In some embodiments, layer 16 may be part of the dielectric 14 and not distinguishable as a separate layer material. The source and drain electrodes or contacts 22 and 24 reside on the first functional layer 20. A second functional layer 28 resides in the channel region between the source and drain contacts 22 and 24. Finally, a semiconductor 30 resides on the second functional layer.

In the embodiment of FIGS. 2-8, the surface modification occurs as a result of silane or other functional coatings and/or plasma or ozone treatments. This modification may also result from attachment using photochemical reactivity. As will be discussed with reference to FIGS. 14-20 an alternative embodiment of the surface modification process may be used. Further, the electronic device shown in FIGS. 2-8 is a bottom-contact TFT. It is possible to apply methods disclosed here to top-contact TFTs. Further, it is also possible to use the gate dielectric as the functionalizable material. These alternatives will be discussed with reference to FIGS. 9-13.

In FIG. 9, the gate dielectric 14 formed over the gate electrode 13 upon substrate 12 is a glass-like polymer or other functionalizable material. Application of the treatment 60 causes at least a portion 62 of layer 14 to become functionalized, in this case hydrophobic. In FIG. 10, the process deposits the semiconductor material 64 on the functional material 62.

In FIG. 11, portions of the functional material 62 from FIG. 10 are removed. Removal may occur by a plasma process or by exposure to ozone, for example. This again exposes the gate dielectric 14, while leaving part of the functionalized portion of layer 14, portion 62, under the semiconductor 64.

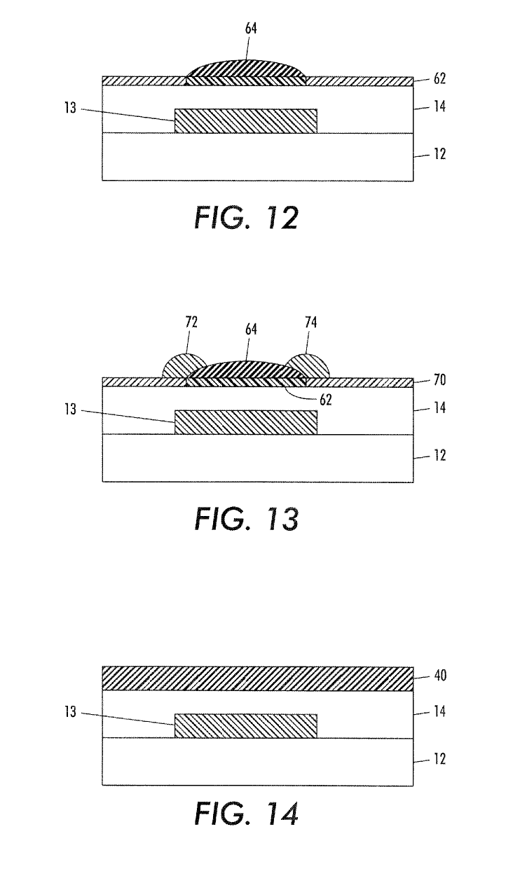

A second functional material 70 is then deposited on the exposed portions of the gate dielectric 14, forming regions of the second functional material 70, shown in FIG. 12. The material may not deposit on the semiconductor due to the lack of functional groups. If some residue of this material becomes deposited on the semiconductor, it may be selectively removed by a rinsing step or it may remain there and it may even contribute to an improved contact resistance between the semiconductor and the subsequently deposited contacts. In FIG. 13, the source and drain contacts 72 and 74 are formed on top of the second functional layer 70 and in contact with the semiconductor material 64. The resulting structure shown in FIG. 13 consists of a top-contact TFT having at least some portion of a first functional material 62 is in the channel region in the channel region between the source and drain contacts 72 and 74.

Both the bottom contact and the top contact devices shown in FIGS. 2-8 and 9-13, respectively, have at least one first conductive or semiconductive feature, such as either the source and the drain contact of a transistor, or the two contacts of a diode such as a photodiode, rectifying diode or light emitting diode as examples, or the semiconductor material, depositing on the first functional material. They have at least one second conductive or semiconductive feature, whichever was not deposited previously, deposited on the second functional material. For purposes of discussion here, the conductive and semiconductive materials will be referred to as the group ‘at least semiconductive material,’ as the conductive material is at least semiconductive, even though it is also ‘fully conductive.’

An alternative embodiment of forming the functional layers of the device is shown in FIGS. 14-20. In FIG. 14, the substrate 12 has residing upon it the gate electrode 13. The gate dielectric 14 covers the gate electrode 13. A material 40 is then deposited on the gate dielectric. The material may be of many different types, but a polymer rich in Si—O—Si groups or rich in hydroxyl groups may have advantages over others in this process. As before, this layer 40 may be a part of the layer 14 and not a separate layer if layer 14 consists already of a material that is functionalizable.

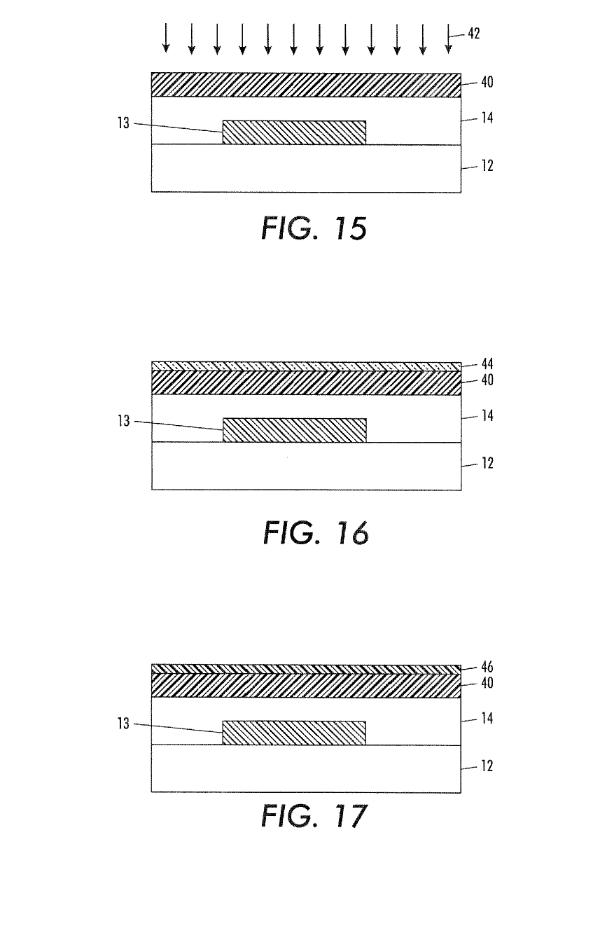

The material 40 may receive a plasma/ozone treatment 42 in FIG. 15. The result is that the top layer of the material 40 changes composition. In the example above, where the material is rich in Si—O—Si, the upper portion of the layer 40 changes to a layer with Si—OH rich groups. FIG. 16 shows this as layer 44 on a layer 40 of the original dielectric material 14.

In FIG. 17, a first modifier reacts with the layer 44 to achieve a first surface energy and alter the layer 44 to become layer 46. The first modifier will generally have proper surface wettability and reactivity, suitable for subsequent printing processes. An example modifier may include a photoreactive benzophenone moiety together with a group that reacts with hydroxyl (OH) groups such as Si(CH₃)₂Cl, SiCl₃, or Si(OCH₃)₃.

The term “photoreactive moiety”, as used herein, refers to a chemical group that responds to an applied external energy source in order to undergo active specie generation, resulting in covalent bonding to an adjacent chemical structure, such as an aliphatic carbon-hydrogen bond. Reactive groups can be chosen that are responsive to various portions of the electromagnetic spectrum, with those responsive to ultraviolet and visible portions of the spectrum, referred to herein as “photoreactive”, being particularly useful. Benzophenone is one example from the group of photoreactive aryl ketones, which includes others such as acetophenone, anthraquinone, anthrone and anthrone-like heterocycles, heterocyclic analogues of anthrone such as those having N, O, or S in the 10-position, or their substituted, such as ring substituted, derivatives.

Another example for generating a photoreactive surface is silanes with aryl azide photoreactive groups where the aryl azide head group is transformed into a highly reactive nitrene upon UV light irradiation. Other photoreactive groups include diazo compounds such as diazoketones, diazophenones, diazoalkanes, or aliphatic azo compounds, such as diazirines, ketenes, azobisisobutyronitrile. Some of these photoreactive groups are for example described in U.S. Pat. No. 5,002,582. The appropriate choice of the modifier allows the printing of continuous, connecting lines with narrow line width and good uniformity in order to build electronic circuits.

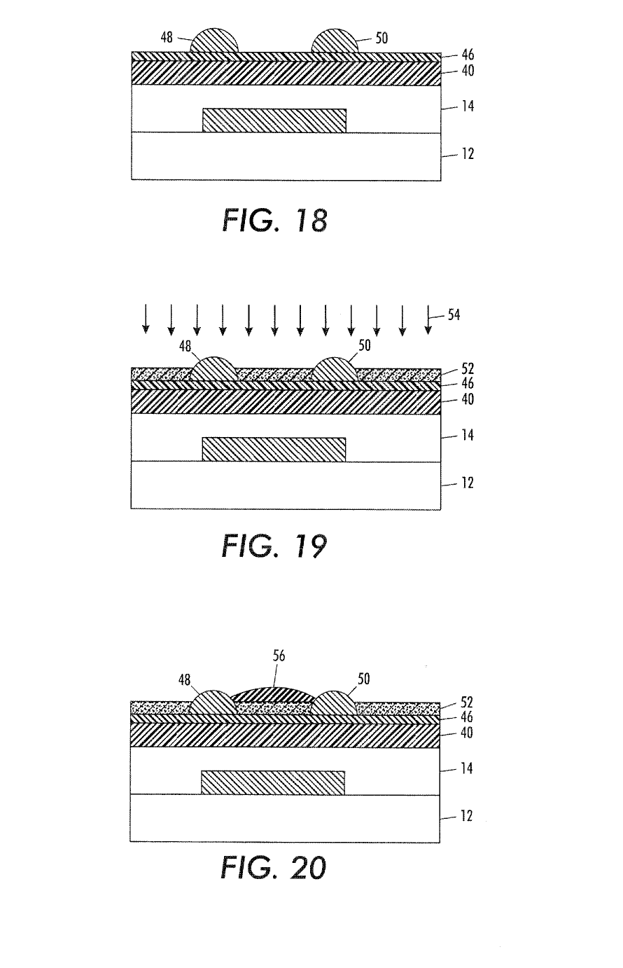

Similar to the embodiment discussed above, the layer 46 becomes the first functional layer on the polymer layer 40. FIG. 18 shows that the source 48 and the drain 50 of the transistor structure are deposited on the first functional layer 46. In FIG. 19, a photochemical reaction caused by exposure to the radiation 54 allows attachment of a layer 52 of a second modifier in order to change the surface energy. This mechanism is also known as photografting and liquid-phase or vapor-phase photografting methods are known. The radiation may be for example ultraviolet light such as light with a wavelength in the range from 200-400 nm (short to long UV) or 1-200 nm (far or extreme UV). However, light with a longer wavelength, such as in the visible spectrum, may also trigger a reaction. Examples of the second modifier include simple n-alkyl substituted benzene or hydrophobic polymers with cross-linkable functionalities such as styrene or allyl groups.

This layer 52 forms the second functional layer and may reside in many areas on the structure, including in the channel region between the source and drain contacts. It only reacts with the exposed portions of the first functional layer and not with the source and drain contacts. Any residual material on the contacts can be removed by simple solvent rinses.

In FIG. 20, the semiconductor 56 is deposited or jet-printed over the second functional layer connecting the source 48 and the drain 50. The semiconductor can be an organic or inorganic semiconductor deposited from solution. The resulting device, shown in FIG. 19, has the substrate 12, a gate electrode 13 having a gate dielectric 14 on it. A functionalizable coating 40 resides on the gate dielectric and has a first functional layer 46 residing upon it. The source and drain electrodes or contacts 48 and 50 reside on the first functional layer 46. A second functional layer 52 resides in the channel region between the source and drain contacts 48 and 50. Finally, a semiconductor 56 resides on the second functional layer. Although this process has been described for a bottom-contact thin-film-transistor, a similar process can also be used for a top-contact thin-film-transistor. In this case the order of deposition for the semiconductor and the source/drain electrodes would be reversed and the functionality of the functional layers would be chosen differently.

Other modifications and variations are possible. In the embodiment discussed with regard to FIGS. 14-19, the modifiers could be self-assembled monolayers, a layer only a single molecule thick formed by adding a solution of the desired molecule onto the substrate and then washing off the excess. It is possible that this process may be applicable to other structures than thin film transistors. It may be applicable to electronic structures having vias, for example.

Similar to the discussion of FIGS. 9-12, this process may also be applicable to top-gate thin-film transistors (TFTs). The source and drain would reside on the substrate, with the gate contact residing on the first functionalized layer. Alternative materials to an organic semiconductor may also be used. These include other solution-processable semiconductors that can be deposited using a carrier fluid, such as nanotubes, nanowires or nanoparticles. The different variations of TFT architectures, whether the gate dielectric is used as the first functionlizable material, etc., are all variations within the scope of the claims. Moreover, apart from TFTs, other electronic devices may be fabricated with similar methods. For example, a diode structure can be built with similar process steps. In this case, the gate electrode would not be required and only two electrically conductive contacts and a semiconductor in between are patterned.

In this manner, a large area of a surface has good surface energy uniformity, making jet printing of the semiconductor much more reliable. This process may work with many different varieties of gate or other dielectrics. Further, any added contact resistance to the source and drain contacts should remain reasonably low, especially in the case of self-assembled monolayers, as there is only one molecule covering the contacts.

It will be appreciated that several of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

What is claimed is:

1. A method of forming an electronic device, comprising:
depositing a dielectric;
forming a first functional material layer having a first surface energy;
depositing from a solution at least one first at least semiconductive feature of the device;
forming a second functional material layer to provide a surface having a second surface energy; and
depositing from a solution at least one second at least semiconductive feature of the device to connect to the first at least semiconductive feature of the device.

2. The method of claim 1, wherein depositing at least one first semiconductive feature comprises printing a conductive contacts, and depositing a second at least semiconductive feature comprises depositing a semiconductor material.

3. The method of claim 1, wherein depositing at least one first at least semiconductive feature comprises depositing a semiconductor material and depositing at least one second at least semiconductive feature comprises printing a at least one conductive contact.

4. The method of claim 1, wherein forming the functional material further comprises depositing a polymer containing silanol or hydroxyl groups.

5. The method of claim 1, wherein forming a functional material layer comprises using a plasma or ozone treatment.

6. The method of claim 1, wherein forming a functional material layer further comprises:
depositing a polymer;
applying a coating of one of silane or silazane to the polymer; and
removing the coating at least partially.

7. The method of claim 6, wherein removing the coating further comprises using one of a plasma treatment, an exposure to ozone or photodecomposition.

8. The method of claim 1, wherein forming a first functional material layer further comprises treating the dielectric to generate reactive groups.

9. The method of claim 1, wherein depositing a second functional material layer further comprises depositing a second silane or silazane coating.

10. The method of claim 1, wherein depositing the first or the second at least semiconductive features further comprises jet-printing the at least semiconductive feature from a solution.

11. The method of claim 1, wherein depositing the at least semiconductive feature from solution further comprises depositing one of an organic semiconductor, a semiconductor precursor or a nanotube, nanorod or nanoparticle-based material.

12. A method of forming an electronic device, comprising:
depositing a first, dielectric material;
depositing a second material;
depositing at least one first at least semiconductive feature of the device on the second material;
altering the second material to form a altered second material; and
depositing at least one at least semiconductive feature from solution to connect the first semiconductive feature of the device.

13. The method of claim 12, wherein altering the second material comprises photochemically attaching a modifier to the second material to form the altered second material.

14. The method of claim 12, wherein the second material is a material that is one of either a material containing chemical functionalities that are photochemically reactive with one of either a polymer or small molecule comprising an aryl ketone or aryl azide functionality or a material reactive to one of either a polymer or small molecule comprising an aryl ketone or aryl azide functionality.

15. The method of claim 12, wherein altering the second material comprises reacting the second material with a first modifier to alter the second material, and the method further comprising photochemically attaching a second modifier to the altered second material to form a third material.

16. The method of claim 15, wherein the first modifier is a material that is one of either a material containing chemical functionalities that are photochemically reactive with one of either a polymer or a small molecule comprising an aryl ketone or aryl azide functionality or a material reactive to one of either a polymer or small molecule comprising an aryl ketone or aryl azide functionality.

17. The method of claim 12, the method further comprising treating the second material with one of either a plasma or ozone.

18. The method of claim 12, wherein depositing conductive features further comprises printing the conductive features.

19. The method of claim 15, wherein photochemically attaching a second modifier further comprises photochemically attaching one of either a material containing one of simple n-alkyl substituted benzene, hydrophobic polymers with cross-linkable functionalities, or styrenes or a material reactive to one of simple n-alkyl substituted benzene, hydrophobic polymers with cross-linkable functionalities, or styrenes.

20. An electronic device, comprising:
a substrate;
a dielectric layer;
a first functional layer having a first surface energy;
at least one printed semiconductor feature on the first functional layer;
a second functional layer having a second surface energy; and
at least one printed conductive feature on the second functional layer.

21. The device of claim 20, the device further comprises at least one a gate electrode under the dielectric layer.

22. The device of claim 21, the device further comprising a thin film transistor.

23. The device of claim 22, the device further comprising one of either a bottom-contact, bottom-gate transistor, or a top-contact, bottom-gate transistor.

24. The device of claim 20, the device further comprising a diode.

25. The device of claim 20, wherein at least one of the first or the second functional layers have a silane moiety.
